(19) United States
(12) Patent Application Publication
(10) Pub. No.: US 2023/0197520 A1
(43) Pub. Date: Jun. 22, 2023

(54) DUMMY DIE PLACEMENT WITHIN A DICING STREET OF A WAFER

(71) Applicant: Intel Corporation, Santa Clara, CA (US)

(72) Inventors: Yi SHI, Chandler, AZ (US); Omkar KARHADE, Chandler, AZ (US); Shawna M. LIFF, Scottsdale, AZ (US); Zhihua ZOU, Gilbert, AZ (US); Ryan MACKIEWICZ, Beaverton, OR (US); Nitin A. DESHPANDE, Chandler, AZ (US); Debendra MALLIK, Chandler, AZ (US); Arnab SARKAR, Chandler, AZ (US)

(21) Appl. No.: 17/557,579

(22) Filed: Dec. 21, 2021

(51) Int. Cl. H01L 21/822; H01L 21/56; H01L 23/31; H01L 23/00

(52) U.S. Cl. CPC H01L 21/822; H01L 21/561; H01L 23/3128; H01L 24/97; H01L 2224/97; H01L 2924/15311

(57) ABSTRACT

Embodiments herein relate to systems, apparatuses, or processes for attaching dummy dies to a wafer that includes a plurality of active dies, where the dummy dies are placed along or in dicing streets where the wafer is to be cut during singulation. In embodiments, the dummy dies may be attached to the wafer using a die attach film, or may be attached using hybrid bonding. Other embodiments may be described and/or claimed.

### FIELD

Embodiments of the present disclosure generally relate to the field of package assemblies, and in particular package assemblies that are singulated from wafers.

### BACKGROUND

Continued reduction in computing package sizes of mobile electronic devices such as smart phones and ultrabooks is a driving force behind increased yield and quality of packages built on wafers.

### BRIEF DESCRIPTION OF THE DRAWINGS

FIG. 1 illustrates cross section side views and a top-down view of a legacy implementation of a plurality of active dies separated by a plurality of dummy dies on a wafer.

FIG. 2 illustrates cross section side views and a top-down view of a plurality of active dies separated by dummy dies that are attached to a wafer by a die attach film (DAF), in accordance with various embodiments.

FIG. 3 illustrates cross section side views and a top-down view of a plurality of active dies separated by a single dummy die that is attached to a wafer by a DAF, in accordance with various embodiments.

FIGS. 4A-4B illustrate cross section side views of a plurality of active dies separated by a single dummy die that is fusion bonded or hybrid bonded to a wafer, in accordance with various embodiments.

FIG. 5 illustrates stages in a manufacturing process using a DAF-based attach for a dummy die between a plurality of active dies on a wafer, in accordance with various embodiments.

FIG. 6 illustrates stages in a manufacturing process for hybrid bonding attach for a dummy die and a plurality of active dies on a wafer, in accordance with various embodiments.

FIGS. 7A-7B schematically illustrate a top view of an example die in wafer form and in singulated form, and a cross section side view of a package assembly, in accordance with various embodiments.

FIG. 8 illustrates an example of a process for placing a dummy die within a dicing street of a substrate, in accordance with various embodiments.

FIG. 9 schematically illustrates a computing device, in accordance with embodiments.

### DETAILED DESCRIPTION

Embodiments of the present disclosure may generally relate to systems, apparatus, techniques, and/or processes directed to attaching dummy dies to a wafer that includes a plurality of active dies, where the dummy dies are placed along dicing streets that identify where the wafer is to be cut during singulation. In embodiments, dummy dies may be attached to the wafer using a DAF. In embodiments, dummy dies may be attached to the wafer using hybrid bonding, where the dummy die may include one or more copper pads where the dummy die couples with the wafer. In embodiments, dummy dies may be attached to the wafer using fusion bonding, where the dummy die has a dielectric layer that couples with a dielectric layer on the wafer. In embodiments, the size of the dummy dies may be increased so that the die may lie within the dicing street and thus the dummy die will be cut during the wafer singulation process.

In some embodiments, active dies may be electronically coupled to the substrate through interconnects e.g. using hybrid bonds, whereas dummy dies may not be electrically coupled to the substrate. An active die may be electrically coupled to the substrate by metal interconnects. An active die may include circuitry such as transistors electrically coupled to the metal interconnects. In some embodiments, the dummy die does not include transistors. In some embodiments, the dummy die does not include metal interconnects.

Dies, or other packages that may be coupled with a wafer, may use hybrid bonding that enables a tighter pitch, for example a pitch less than 9 μm, and therefore is able to increase bandwidth density between dies. Similar to other die-to-wafer interconnects, such as thermal compression bonding (TCB), dummy dies may be used to maintain good mechanical integrity and thermal performance for dies coupled with the wafer, in particular after die singulation and subsequent processing.

Typically, dummy dies have a high aspect ratio and a minimum die width, often less than 1 mm. The dummy dies are used to fill empty space on top of the bottom die, where no active circuit from another chip or die is needed but the presence of silicon can benefit wafer assembly bow and thermal dissipation of the underlying wafer. For hybrid bonding, because high precision die placement is required, for example 200 nm at 3-Sigma, the bonding techniques currently available cannot easily process dummy dies with a minimum die with of less than 1 mm.

Embodiments described herein may be accommodated with legacy manufacturing techniques and therefore enable cost savings, particularly for dies and packages that utilize hybrid bonding to achieve higher performance and better power efficiency.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

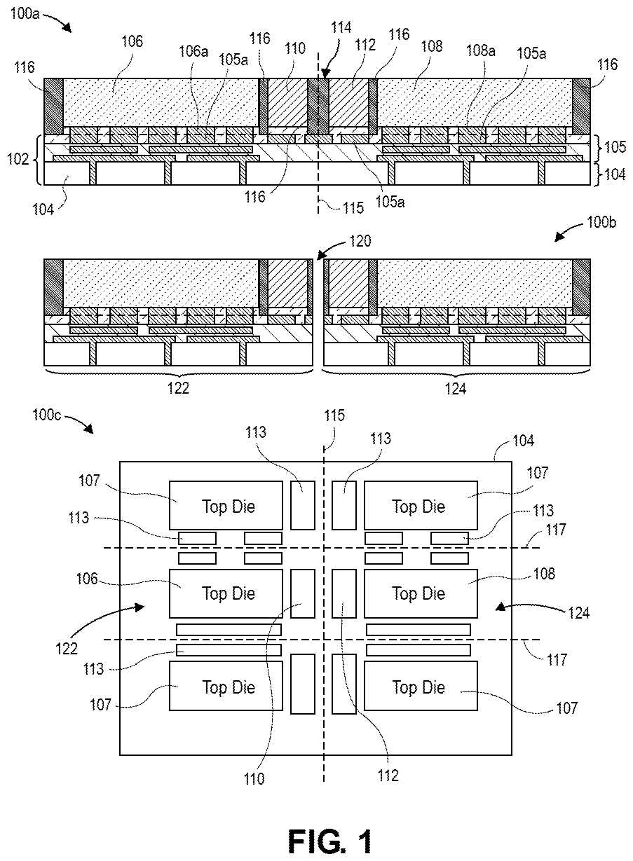

FIG. 1 illustrates cross section side views and a top-down view of a legacy implementation of a plurality of active dies separated by a plurality of dummy dies on a wafer. Diagram 100a is a cross section side view of a legacy implementation of a substrate 102 that includes a bottom wafer 104 onto which a redistribution layer (RDL) 105 that includes copper pads 105a is applied. A first active die 106 and a second active die 108 are coupled to the substrate 102. In embodiments, the first active die 106 may be hybrid bonded to the substrate 102 by hybrid bonding copper pads 106a of first active die 106 to the copper pads 105a of the substrate 102. Similarly, the second active die 108 may be hybrid bonded to the substrate 102 by hybrid bonding copper pads 108a of the second active die 108 to the copper pads 105a of the substrate 102. In embodiments, the substrate 102 may also be referred to as a wafer.

A first dummy die 110 and a second dummy die 112 may be coupled with the substrate 102 using, for example, thermo-compression bonding (TCB). In embodiments, a space 114 may exist between the first dummy die 110 and the second dummy die 112, which may define a dicing street 115 that may be cut along or sawed during singulation of the wafer 104. In embodiments, a molding compound 116 may be applied to surround the first active die 106, the second active die 108, the first dummy die 110, and the second dummy die 112. Diagram 100b is a cross section side view of the legacy implementation shown in diagram 100 where singulation 120 has occurred, creating separate packages 122, 124.

Diagram 100c is a top-down view of legacy implementation of a wafer 104 that shows the first active die 106, the second top die 108, and dummy dies 110, 112. Dicing street 115 is also shown that is used to separate package 122 from package 124. Note that other dies 107, other dicing streets 117, and other dummy dies 113 are also shown.

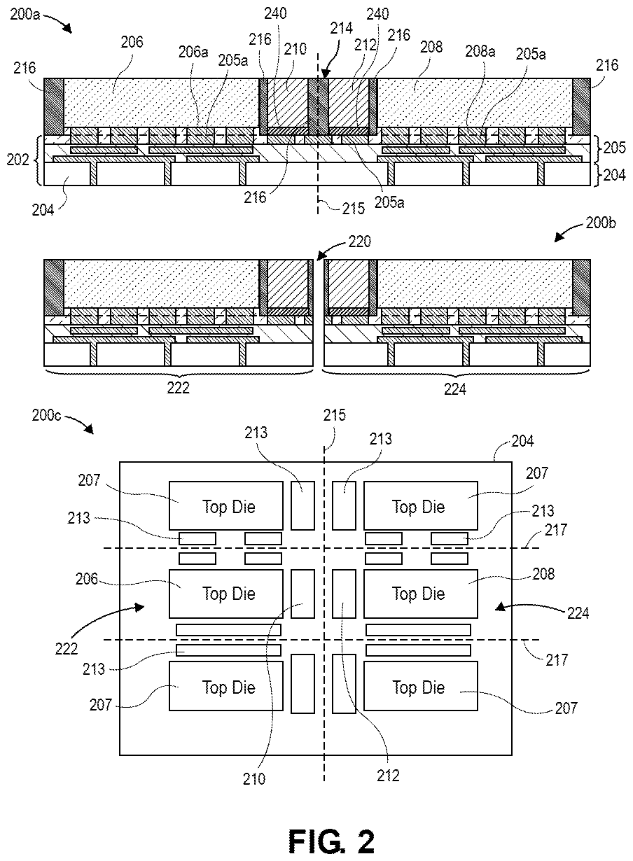

FIG. 2 illustrates cross section side views and a top-down view of a plurality of active dies separated by dummy dies that are attached to a wafer by a DAF, in accordance with various embodiments. Diagram 200a, which may be similar to diagram 100a of FIG. 1, is a cross section side view of an embodiment that includes a substrate 202 with a bottom wafer 204 onto which a RDL 205 has been created that includes copper pads 205a. A first active die 206 and a second active die 208 are coupled to the substrate 202. In embodiments, the first active die 206 may be hybrid bonded to the substrate 202 by hybrid bonding copper pads 206a of first active die 206 to the copper pads 205a of the substrate 202. Similarly, the second active die 208 may be hybrid bonded to the substrate 202 by hybrid bonding copper pads 208a of the second active die 208 to the copper pads 205a of the substrate 202.

A first dummy die 210 and a second dummy die 212 may be coupled with the substrate 202 using a DAF 240. In embodiments, the DAF 240 may be applied to the dummy dies 210, 212 prior to attachment to the substrate 202, or may be first applied to the substrate 202. In embodiments, the DAF 240 may be a single layer on top of the substrate 202. In embodiments the DAF may be an adhesive material. In embodiments, the DAF 240 may include materials such as epoxies, maleimides, bismaleimides, acrylates, silicones, cyanate esters or a combination there of with thermally conductive aluminum nitride or silicon nitride particles or insulative particles such as silicathe.

In embodiments, a space 214 may exist between the first dummy die 210 and the second dummy die 212, which may define a dicing street 215 that may be used during singulation of the wafer 204. In embodiments, a molding compound 216 may be applied to surround the first active die 206, the second active die, 208, the first dummy die 210, and the second dummy die 212. Diagram 200b is a cross section side view of an embodiment that uses DAF 240 as shown in diagram 200a where singulation 220 has occurred, creating separate packages 222, 224.

Diagram 200c is a top-down view of an embodiment that uses DAF 240 as shown in diagram 200a that includes a wafer 204 that shows the first top die 206, the second top die 208, and dummy dies 210, 212. Dicing street 215 is also shown that is used to separate package 222 from package 224. Note that other dies 207, other dicing streets 217, and other dummy dies 213 are also shown.

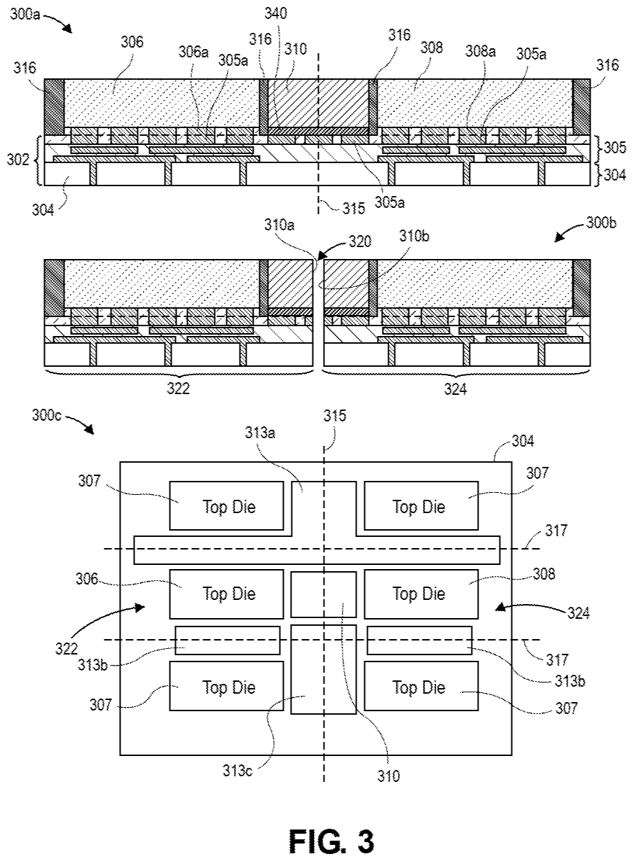

FIG. 3 illustrates cross section side views and a top-down view of a plurality of active dies separated by a single dummy die that is attached to a wafer by a DAF, in accordance with various embodiments. Diagram 300a, which may be similar to diagram 200a of FIG. 2, is a cross section side view of an embodiment that includes a substrate 302 with a bottom wafer 304 onto which a RDL 305 has been created that includes copper pads 305a. A first active die 306 and a second active die 308 are coupled to the substrate 302. In embodiments, the first active die 306 may be hybrid bonded to the substrate 302 by hybrid bonding copper pads 306a of first active die 306 to the copper pads 305a of the substrate 302. Similarly, the second active die 308 may be hybrid bonded to the substrate 302 by hybrid bonding copper pads 308a of the second active die 308 to the copper pads 305a of the substrate 302.

A single dummy die 310 may be coupled with the substrate 302 using a DAF 340. In embodiments, the DAF 340 may be applied to the dummy die 310 prior to attachment to the substrate 302, or may be first applied to the substrate 302. In embodiments, the DAF 340 may be a single layer on top of the substrate 302.

In embodiments, a molding compound 316 may be applied to surround the first active die 306, the second active die, 308, and the dummy die 310. Diagram 300b is a cross section side view of an embodiment that uses DAF 340 as shown in diagram 300a where singulation 320 has occurred, creating separate packages 322, 324. Note that the singulation process has cut through the dummy die 310, exposing a first side 310a at the edge of first package 322, and exposing a second side 310b at the edge of the second package 324.

Diagram 300c is a top-down view of an embodiment that uses DAF 340 as shown in diagram 300a that includes a wafer 304 that shows the first top die 306, the second top die 308, and dummy die 310. Dicing street 315 is also shown that is used to separate package 322 from package 324. Note that other dies 307 and other dicing streets 317 in other embodiments are also shown.

In embodiments, various shapes and sizes of dummy dies 313a, 313b, 313c are also shown. In particular, dummy dies 313a, 313c may be positioned along multiple dicing streets 315, 317. In embodiments, a dummy die 313a may be adjacent to three or more active dies 306, 307, 308.

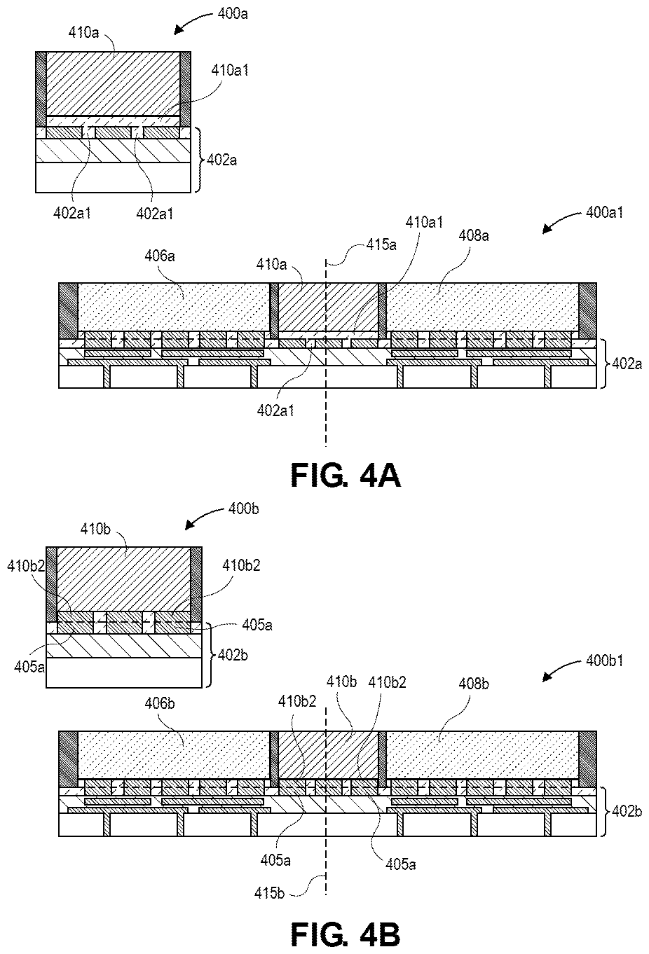

FIGS. 4A-4B illustrate cross section side views of a plurality of active dies separated by a single dummy die that is fusion bonded or hybrid bonded to a wafer, in accordance with various embodiments. FIG. 4A includes a partial package 400a that includes a dummy die 410a that is fusion bonded to substrate 402a, which may be similar to dummy die 310 and substrate 302 of FIG. 3. With fusion bonding, the dielectric 410a1 that is a part of the dummy die 410a is bonded with the dielectric 402a1 at the surface of the substrate 402a, which may be performed at room temperature, and subsequently followed by a high-temperature anneal process.

Cross section side view 400a1 shows the dummy die 410a after it has been fusion bonded, and is located between active die 406a and active die 408a, which may be similar to active dies 306, 308 of FIG. 3. The dicing street 415a, which may be similar to dicing street 315 of FIG. 3, passes through the fusion bonded dummy die 410a.

FIG. 4B includes a partial package 400b that includes a dummy die 410b that is hybrid bonded to substrate 402b, which may be similar to dummy die 310 and substrate 302 of FIG. 3. With hybrid bonding, copper pads 410b2 that are a part of the dummy die 410b are bonded with copper pads 405a, which may be similar to copper pads 105a of FIG. 1, at the surface of the substrate 402b which may be performed at room temperature, and subsequently followed by a high-temperature anneal process.

Cross section side view 400b1 shows the dummy die 410b after it has been bonded, and is located between active die 406b and active die 408b, which may be similar to active dies 306, 308 of FIG. 3. The dicing street 415b, which may be similar to dicing street 315 of FIG. 3, passes through the hybrid bonded dummy die 410b.

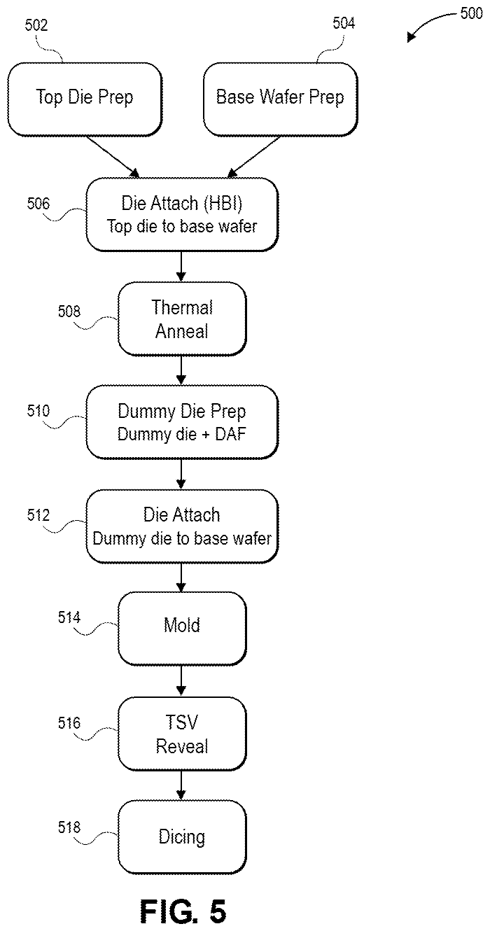

FIG. 5 illustrates stages in a manufacturing process using a DAF-based attach for a dummy die between a plurality of active dies on a wafer, in accordance with various embodiments. Process 500 may be implemented using the processes, techniques, apparatus, and/or systems described herein, and in particular with respect to FIGS. 1-4B.

At block 502, the process may include top die preparation. In embodiments, the top die may be similar to the top die 206, 208 of FIG. 2, or top die 306, 308 of FIG. 3.

At block 504, the process may further include base wafer preparation. The base wafer may be similar to substrate 202, that includes wafer 204 of FIG. 2, or similar to substrate 302 that includes wafer 304 of FIG. 3.

At block 506, the process may further include attaching the top die to the base wafer in preparation for a hybrid bonding process.

At block 508, the process may further include applying a thermal anneal to complete the hybrid bonding process.

At block 510, the process includes preparing a dummy die. In embodiments, the dummy die may be similar to dummy dies 210, 212 of FIG. 2, or dummy die 310 of FIG. 3. In embodiments, the preparation process may include identifying and applying a DAF, such as DAF 240 of FIG. 2 or DAF 340 of FIG. 3, to a surface of the dummy die.

At block 512, the process may further include attaching the prepared dummy die to the prepared base wafer, as discussed with respect to block 504 above.

At block 514, the process may further include applying a mold compound, such as molding compound 216 of FIG. 2.

At block 516, the process may further include performing a through silicon via (TSV) reveal.

At block 518, the process may further include dicing. In embodiments, this is similar to singulation of the wafer along a dicing street, which may be similar to dicing street 215 of FIG. 2, or dicing street 315 of FIG. 3.

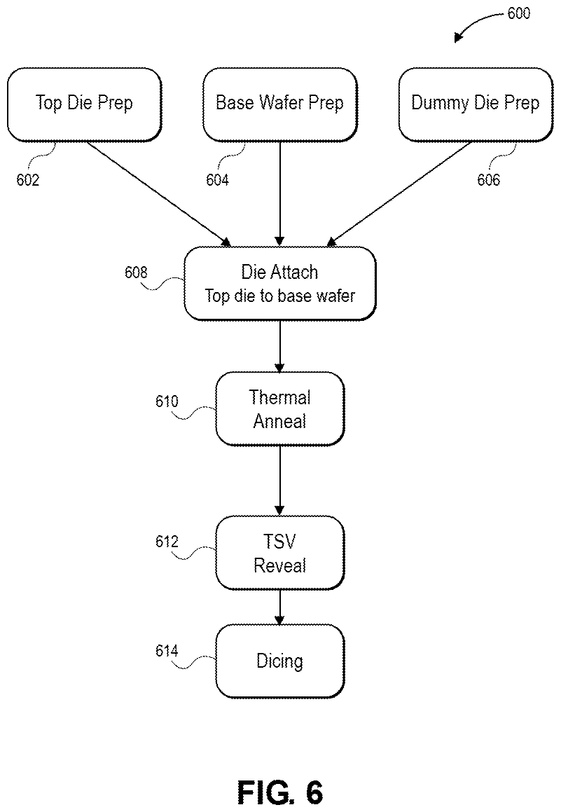

FIG. 6 illustrates stages in the manufacturing process for hybrid bonding attach for a dummy die and a plurality of active dies on a wafer, in accordance with various embodiments. Process 600 may be implemented using the processes, techniques, apparatus, and/or systems described herein, and in particular with respect to FIGS. 1-4B.

At block 602, the process may include top die preparation. In embodiments, the top die may be similar to the top dies 406a, 408a of FIG. 4A or top dies 406b, 408b of FIG. 4B.

At block 604, the process may further include base wafer preparation. The base wafer may be similar to substrate 402a of FIG. 4A, or substrate 402b of FIG. 4B.

At block 606, the process may further include preparing a dummy die. In embodiments, the dummy die may be similar to dummy die 410a of FIG. 4A, or dummy die 410b of FIG. 4B. In embodiments, the preparation process may include applying a dielectric layer to a bottom of the dummy die in preparation for fusion bonding as discussed with respect to FIG. 4A. In embodiments, the preparation process may include applying one or more copper pads to a bottom of the dummy die in preparation for hybrid bonding as discussed with respect to FIG. 4B.

At block 608, the process may further include performing a die attach, where the top dies, prepared at block 602, and the dummy die, prepared at block 606, are attached to the base wafer, prepared at block 604. This is in preparation for hybrid bonding or fusion bonding.

At block 610, the process may further include performing a thermal anneal to complete the hybrid bonding or fusion bonding process.

At block 612, the process may further include performing a through silicon via (TSV) reveal. In embodiments, the reveal requires controlled topography if after assembly, and the modulus and space between the dies can be important to ensure good reveal across the wafer. By using dummy die, this process may be kept more tightly in line.

At block 614, the process may further include dicing. In embodiments, this is similar to singulation of the wafer along a dicing street, which may be similar to dicing street 415a of FIG. 4A or dicing street 415b of FIG. 4B.

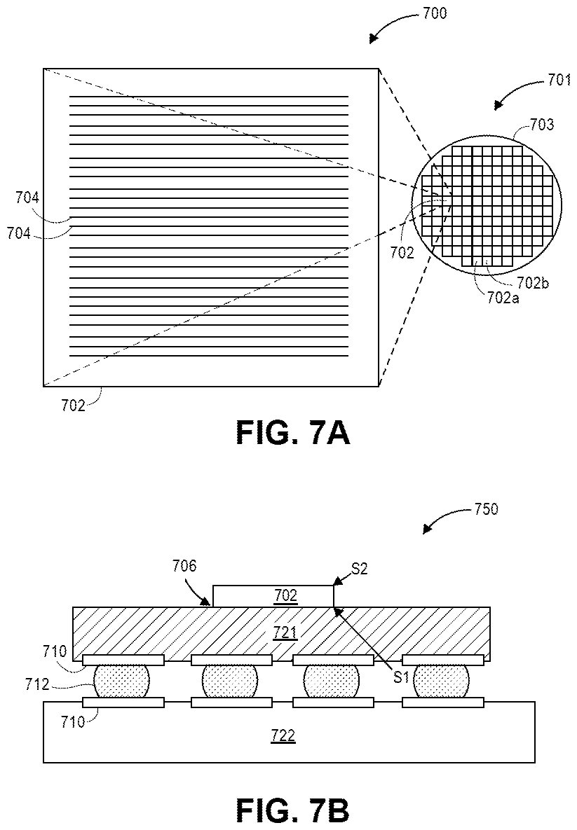

FIGS. 7A-7B schematically illustrate a top view of an example die in wafer form and in singulated form, and a cross section side view of a package assembly, in accordance with various embodiments. FIG. 7A schematically illustrates a top view of an example die 702 in a wafer form 701 and in a singulated form 700, in accordance with some embodiments. In some embodiments, die 702 may be one of a plurality of dies, e.g., dies 702, 702a, 702b, of a wafer 703 comprising semiconductor material, e.g., silicon or other suitable material. The plurality of dies, e.g., dies 702, 702a, 702b, may be formed on a surface of wafer 703. At least one of the plurality of dies may be a dummy die that is placed along or within a dicing street on the wafer 703 that is cut during a singulation process. The dummy die may be attached using a DAF, or using hybrid bonding or fusion bonding techniques as described herein.

Each of the dies 702, 702a, 702b, may be a repeating unit of a semiconductor product that includes devices as described herein. For example, die 702 may include circuitry having transistor elements such as, for example, one or more channel bodies 704 (e.g., fin structures, nanowires, and the like) that provide a channel pathway for mobile charge carriers in transistor devices. Although one or more channel bodies 704 are depicted in rows that traverse a substantial portion of die 702, it is to be understood that one or more channel bodies 704 may be configured in any of a wide variety of other suitable arrangements on die 702 in other embodiments.

After a fabrication process of the device embodied in the dies is complete, wafer 703 may undergo a singulation process in which each of dies, e.g., die 702, is separated from one another to provide discrete “chips” of the semiconductor product. Wafer 703 may be any of a variety of sizes. In some embodiments, wafer 703 has a diameter ranging from about 25.4 mm to about 450 mm. Wafer 703 may include other sizes and/or other shapes in other embodiments. According to various embodiments, the one or more channel bodies 704 may be disposed on a semiconductor substrate in wafer form 701 or singulated form 700. One or more channel bodies 704 described herein may be incorporated in die 702 for logic, memory, or combinations thereof. In some embodiments, one or more channel bodies 704 may be part of a system-on-chip (SoC) assembly.

FIG. 7B schematically illustrates a cross-section side view of an integrated circuit (IC) assembly 750, in accordance with some embodiments. In some embodiments, IC assembly 750 may include one or more dies, e.g., die 702, hybrid bonded using techniques described herein to package substrate 721. Die 702 may include one or more channel bodies 704 that serve as channel bodies of multi-threshold voltage transistor devices. In some embodiments, package substrate 721 may be electrically coupled with a circuit board 722 as is well known to a person of ordinary skill in the art. Die 702 may represent a discrete product made from a semiconductor material (e.g., silicon) using semiconductor fabrication techniques such as thin film deposition, lithography, etching, and the like used in connection with forming Complementary Metal Oxide Semiconductor (CMOS) devices. In some embodiments, die 702 may be, include, or be a part of a processor, memory, SoC or ASIC in some embodiments.

Die 702 can be attached to package substrate 721 according to a wide variety of suitable configurations including, for example, being directly coupled with package substrate 721 in a flip-chip configuration, as depicted. In the flip-chip configuration, an active side S1 of die 702 including circuitry is attached to a surface of package substrate 721 using hybrid bonding structures as described herein that may also electrically couple die 702 with package substrate 721. Active side S1 of die 702 may include multi-threshold voltage transistor devices as described herein. An inactive side S2 of die 702 may be disposed opposite to active side S1.

In some embodiments, package substrate 721 is an epoxy-based laminate substrate having a core and/or build-up layers such as, for example, an Ajinomoto Build-up Film (ABF) substrate. Package substrate 721 may include other suitable types of substrates in other embodiments including, for example, substrates formed from glass, ceramic, or semiconductor materials.

Package substrate 721 may include electrical routing features configured to route electrical signals to or from die 702. The electrical routing features may include pads or traces (not shown) disposed on one or more surfaces of package substrate 721 and/or internal routing features (not shown) such as trenches, vias, or other interconnect structures to route electrical signals through package substrate 721. In some embodiments, package substrate 721 may include electrical routing features such as pads (not shown) configured to receive the respective die-level interconnect structures 706 of die 702.

Circuit board 722 may be a printed circuit board (PCB) comprising an electrically insulative material such as an epoxy laminate. Circuit board 722 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 702 through circuit board 722. Circuit board 722 may comprise other suitable materials in other embodiments. In some embodiments, circuit board 722 is a motherboard as is well known to a person of ordinary skill in the art.

Package-level interconnects such as, for example, solder balls 712 may be coupled to one or more pads 710 on package substrate 721 and/or on circuit board 722 to form corresponding solder joints that are configured to further route the electrical signals between package substrate 721 and circuit board 722. Pads 710 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 721 with circuit board 722 may be used in other embodiments.

IC assembly 750 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 702 and other components of IC assembly 750 may be used in some embodiments.

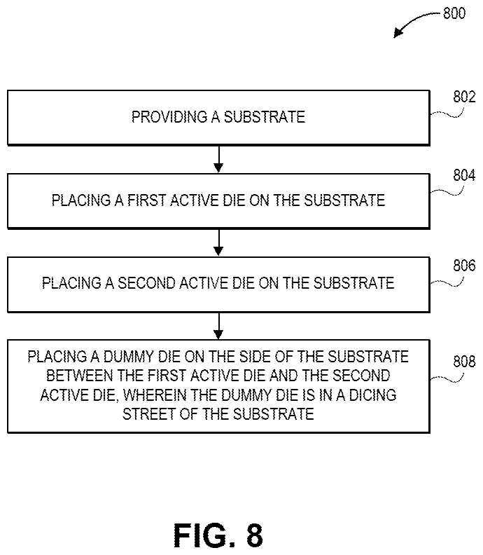

FIG. 8 illustrates an example of a process for placing a dummy die within a dicing street of a substrate, in accordance with embodiments. Process 800 may be performed by one or more elements, techniques, or systems that may be described herein, and in particular with respect to FIGS. 2-7B. In embodiments, the substrate may also be a wafer.

At block 802, the process may include providing a substrate.

At block 804, the process may further include placing a first active die on the substrate.

At block 806, the process may further include placing a second active die on the substrate.

At block 808, the process may further include placing a dummy die on the side of the substrate between the first active die and the second active die, wherein the dummy die is in a dicing street of the substrate.

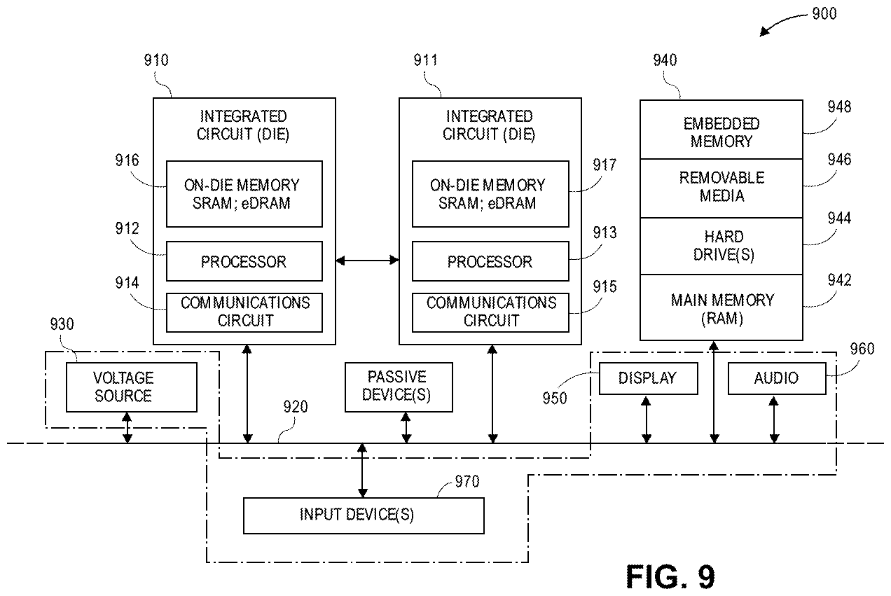

FIG. 9 is a schematic of a computer system 900, in accordance with an embodiment of the present invention. The computer system 900 (also referred to as the electronic system 900) as depicted can embody a dummy die placed within a dicing street of a wafer, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, a dummy die placed within a dicing street of a wafer, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having a dummy die placed within a dicing street of a wafer, according to any of the several disclosed embodiments and their equivalents, an electronic system, a computer system, one or more methods of fabricating an integrated circuit, and one or more methods of fabricating an electronic assembly that includes a package substrate having a dummy die placed within a dicing street of a wafer, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a dummy die placed within a dicing street of a wafer embodiments and their equivalents. A foundation substrate may be included, as represented by the dashed line of FIG. 9. Passive devices may also be included, as is also depicted in FIG. 9.

### EXAMPLES

The following paragraphs describe examples of various embodiments.

Example 1 is a package comprising: a substrate; an active die on the substrate; a dummy die on the substrate proximate to an edge of the active die, the dummy die physically coupled with the substrate with a DAF; and wherein the dummy die is at or near an edge of the package.

Example 2 includes the package of example 1, or of any other example or embodiment described herein, wherein a mold compound is between the dummy die and the edge of the package.

Example 3 may include the package of example 1, or of any other example or embodiment described herein, wherein an edge of the dummy is at the edge of package.

Example 4 may include the package of example 3, or of any other example or embodiment described herein, wherein the edge of the dummy die is singulated.

Example 5 may include the package of example 1, or of any other example or embodiment described herein, wherein the active die is a first active die; and further comprising: a second active die proximate to the first active die; and wherein the dummy die is proximate to an edge of the second active die.

Example 6 may include the package of example 5, or of any other example or embodiment described herein, wherein the edge of the first active die is a first edge of the first active die; and wherein the dummy die is proximate to the second edge of the first active die.

Example 7 may include the package of example 5, or of any other example or embodiment described herein, wherein the first active die is electrically coupled with the second active die.

Example 8 may include the package of example 1, or of any other example or embodiment described herein, wherein the substrate includes a portion of a silicon wafer.

Example 9 may include a package comprising a substrate; an active die on the substrate; a dummy die bonded to the substrate proximate to an edge of the active die, the dummy die bonded in a selected one of: hybrid bonded or fusion bonded; and wherein the dummy die is at or near an edge of the package.

Example 10 may include the package of example 9, or of any other example or embodiment described herein, wherein the dummy die includes one or more metal pads at a bottom of the dummy die that are bonded, respectively, with one or more metal pads in the substrate.

Example 11 may include the package of example 10, or of any other example or embodiment described herein, wherein the metal pads include copper.

Example 12 may include the package of example 9, or of any other example or embodiment described herein, wherein an edge of the dummy is at the edge of package.

Example 13 may include the package of example 9, or of any other example or embodiment described herein, wherein the edge of the dummy die is singulated.

Example 14 may include the package of example 9, or of any other example or embodiment described herein, wherein the active die is a first active die; and further comprising: a second active die proximate to the first active die; and wherein the dummy die is proximate to an edge of the second active die.

Example 15 may include the package of example 14, or of any other example or embodiment described herein, wherein the edge of the first active die is a first edge of the first active die; and wherein the dummy die is proximate to the second edge of the first active die.

Example 16 may include the package of example 14, or of any other example or embodiment described herein, wherein the first active die is electrically coupled with the second active die.

Example 17 may include a method comprising: providing a substrate; placing a first active die on the substrate; placing a second active die on the substrate; and placing a dummy die on the side of the substrate between the first active die and the second active die, wherein the dummy die is in a dicing street of the substrate.

Example 18 may include the method of example 17, or of any other example or embodiment described herein, wherein placing the dummy die on the side of the substrate further includes: placing a layer of DAF on a portion of the side of the substrate between the first active die and the second active die; and placing the dummy die on the layer of DAF.

Example 19 may include the method of example 17, or of any other example herein, wherein placing the dummy die on the side of the substrate further includes fusion bonding the dummy die to the side of the substrate.

Example 20 may include the method of example 17, or of any other example or embodiment described herein, wherein the dummy die includes one or more metal pads on an edge of the dummy die; and further comprising hybrid bonding the edge of the dummy die to the edge of the substrate.

Example 21 may include the method of example 20, or of any other example or embodiment described herein, wherein the metal pads include copper.

Example 22 may include a wafer comprising: a substrate; a first active die coupled with a side of the substrate; a second active die coupled with the side of the substrate; and a dummy die coupled with the side of the substrate, wherein the dummy die is in a dicing street between the first active die and the second active die.

Example 23 may include the wafer of example 22, or of any other example or embodiment described herein, wherein the dummy die is coupled with the substrate using a DAF.

Example 24 may include the wafer of example 22, or of any other example or embodiment described herein, wherein the dummy die is coupled with the substrate using fusion bonding.

Example 25 may include the wafer of example 22, or of any other example or embodiment described herein, wherein the dummy die includes one or more metal pads at a side of the dummy die proximate to the side of the substrate; and wherein the dummy die is fusion bonded to the substrate.

Example 26 is a package comprising: a substrate; a first die on the substrate, the first die electrically coupled to the substrate by metal interconnects; a second die on the substrate, the second die not electrically coupled to the substrate by metal interconnects; and wherein the second die is physically coupled with the substrate by an adhesive material.

Example 27 may include the package of example 26, or of any other example or embodiment described herein, wherein the first die includes one or more metal pads at a bottom of the first die that are bonded, respectively, with one or more metal pads in the substrate.

Example 28 may include a package of example 27, or of any other example or embodiment described herein, wherein the metal pads comprise copper.

Example 29 may include the package of example 26, or of any other example or embodiment herein, wherein the first die includes transistors, and wherein the second die does not include transistors.

Example 30 may include the package of example 26, or of any other example or embodiment herein, wherein the first die is an active die, and wherein the second die is a dummy die.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments.

Moreover, some embodiments may include apparatuses or systems having any suitable means for carrying out the various operations of the above-described embodiments. The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising
a substrate;
an active die on the substrate;
a dummy die on the substrate proximate to an edge of the active die, the dummy die physically coupled with the substrate with a DAF; and
wherein the dummy die is at or near an edge of the package.

2. The package of claim 1, wherein a mold compound is between the dummy die and the edge of the package.

3. The package of claim 1, wherein an edge of the dummy is at the edge of package.

4. The package of claim 3, wherein the edge of the dummy die is singulated.

5. The package of claim 1, wherein the active die is a first active die; and further comprising:
a second active die proximate to the first active die; and
wherein the dummy die is proximate to an edge of the second active die.

6. The package of claim 5, wherein the edge of the first active die is a first edge of the first active die; and wherein the dummy die is proximate to the second edge of the first active die.

7. The package of claim 5, wherein the first active die is electrically coupled with the second active die.

8. The package of claim 1, wherein the substrate includes a portion of a silicon wafer.

9. A package comprising
a substrate;
an active die on the substrate;
a dummy die bonded to the substrate proximate to an edge of the active die, the dummy die bonded in a selected one of: hybrid bonded or fusion bonded; and
wherein the dummy die is at or near an edge of the package.

10. The package of claim 9, wherein the dummy die includes one or more metal pads at a bottom of the dummy die that are bonded, respectively, with one or more metal pads in the substrate.

11. The package of claim 10, wherein the metal pads include copper.

12. The package of claim 9, wherein an edge of the dummy is at the edge of package.

13. The package of claim 9, wherein the edge of the dummy die is singulated.

14. The package of claim 9, wherein the active die is a first active die; and further comprising:
a second active die proximate to the first active die; and
wherein the dummy die is proximate to an edge of the second active die.

15. The package of claim 14, wherein the edge of the first active die is a first edge of the first active die; and wherein the dummy die is proximate to the second edge of the first active die.

16. The package of claim 14, wherein the first active die is electrically coupled with the second active die.

17. A package comprising:
a substrate;
a first die on the substrate, the first die electrically coupled to the substrate by metal interconnects;
a second die on the substrate, the second die not electrically coupled to the substrate by metal interconnects; and
wherein the second die is physically coupled with the substrate by an adhesive material.

18. The package of claim 17, wherein the first die includes one or more metal pads at a bottom of the first die that are bonded, respectively, with one or more metal pads in the substrate.

19. The package of claim 18, wherein the metal pads comprise copper.

20. The package of claim 17, wherein the first die includes transistors, and wherein the second die does not include transistors.

21. The package of claim 17, wherein the first die is an active die, and wherein the second die is a dummy die.

22. A wafer comprising:
a substrate;
a first active die coupled with a side of the substrate;
a second active die coupled with the side of the substrate; and
a dummy die coupled with the side of the substrate, wherein the dummy die is in a dicing street between the first active die and the second active die.

23. The wafer of claim 22, wherein the dummy die is coupled with the substrate using a DAF.

24. The wafer of claim 22, wherein the dummy die is coupled with the substrate using fusion bonding.

25. The wafer of claim 22, wherein the dummy die includes one or more metal pads at a side of the dummy die proximate to the side of the substrate; and wherein the dummy die is fusion bonded to the substrate.
